(19) United States
(12) Patent Application Publication
(10) Pub. No.: US 2026/0057957 A1
(43) Pub. Date: Feb. 26, 2026

(54) OPERATING METHOD OF MEMORY APPARATUS, MEMORY SYSTEM, AND OPERATING METHOD OF MEMORY SYSTEM

(71) Applicant: SK hynix Inc., Icheon-si (KR)

(72) Inventors: Gap Sok DO, Icheon-si (KR); Beom Seok Lee, Icheon-si (KR)

(21) Appl. No.: 19/182,350

(22) Filed: Apr. 17, 2025

(30) Foreign Application Priority Data
Aug. 26, 2024 (KR) 10-2024-0114451

(51) Int. Cl. G11C 29/52; G11C 29/00; G11C 29/02

(52) U.S. Cl. CPC G11C 29/52; G11C 29/022; G11C 29/76

(57) ABSTRACT

A memory system may include a memory apparatus including a memory cell array in which active areas of each pair of adjacent memory cells are formed to face each other, the memory cell array including a plurality of memory cells, a controller that controls the memory apparatus, and a buffer memory that stores data received from the controller and provides the stored data to the controller.

### CROSS-REFERENCE TO RELATED APPLICATION

This application claims priority under 35 U.S.C. § 119(a) to Korean Patent Application No. 10-2024-0114451 filed on Aug. 26, 2024, which is incorporated herein by reference in its entirety.

### BACKGROUND

### 1. Technical Field

Embodiments of the present disclosure relate to integrated circuit technology, and particularly, to an operating method of a memory apparatus, a memory system including the memory apparatus, and an operating method of the memory system.

### 2. Related Art

Recently, with the miniaturization, low power consumption, high performance, diversification, and the like of electronic devices, there is a demand for memories capable of storing information in various electronic appliances such as computers and portable communication devices. In addition, research on memories with various characteristics is also ongoing.

Memories under research include memories that can store data by using the characteristic of switching between different resistance states according to an applied voltage or current. Such memories include a resistive random access memory (RRAM), a phase-change random access memory (PRAM), a ferroelectric random access memory (FRAM), a magnetic random access memory (MRAM), an E-fuse, and the like.

### SUMMARY

In an embodiment, an operating method of a memory apparatus may include: a step of selecting a pair of vertical bit lines from a plurality of vertical bit lines formed by penetrating a word plane; a step of floating the word plane; and a step of applying a first voltage to one of the pair of vertical bit lines selected in the step of selecting and applying a second voltage to the other vertical bit line.

In an embodiment, an operating method of a memory system may include: a step of correcting an error in data received from a memory apparatus, accumulating information on an address where the error has occurred, and storing the accumulated information; a step of determining a memory cell as a fail cell when the same information on the address where the error has occurred is continuously accumulated; a step of temporarily storing data of a memory cell adjacent to the fail cell; a step of changing a state of the adjacent memory cell to a set state; a step of applying voltages with different levels to a vertical bit line of the fail cell and a vertical bit line of the adjacent memory cell, respectively; and a step of storing the data stored in the step of temporarily storing in the adjacent memory cell.

In an embodiment, a memory system may include: a memory apparatus including a memory cell array in which active areas of each pair of adjacent memory cells are formed to face each other, the memory cell array including a plurality of memory cells; a controller that controls the memory apparatus; and a buffer memory that stores data received from the controller and provides the stored data to the controller.

### BRIEF DESCRIPTION OF THE DRAWINGS

FIG. 1 illustrates a memory cell array in accordance with an embodiment of the present disclosure.

FIGS. 2A and 2B illustrate a memory cell included in a memory cell array in accordance with an embodiment of the present disclosure.

FIG. 3 illustrates a memory cell included in a memory cell array in accordance with an embodiment of the present disclosure.

FIGS. 4 and 5 describe a write operation of a memory cell array in accordance with an embodiment of the present disclosure.

FIGS. 6 and 7 describe a firing operation of a memory cell array in accordance with an embodiment of the present disclosure.

FIG. 8 describes an operation of a memory apparatus in accordance with an embodiment of the present disclosure.

FIG. 9 illustrates a memory system in accordance with an embodiment of the present disclosure.

FIG. 10 is a flowchart for describing an operation of a memory system in accordance with an embodiment of the present disclosure.

### DETAILED DESCRIPTION

Various embodiments relate to operating methods for controlling the formation position of an active area in a memory cell and repairing a failed cell using the same.

In accordance with embodiments of the present disclosure, it is possible to enhance data storage reliability and durability of a memory.

Hereafter, embodiments in accordance with the technical spirit of the present disclosure will be described with reference to the accompanying drawings.

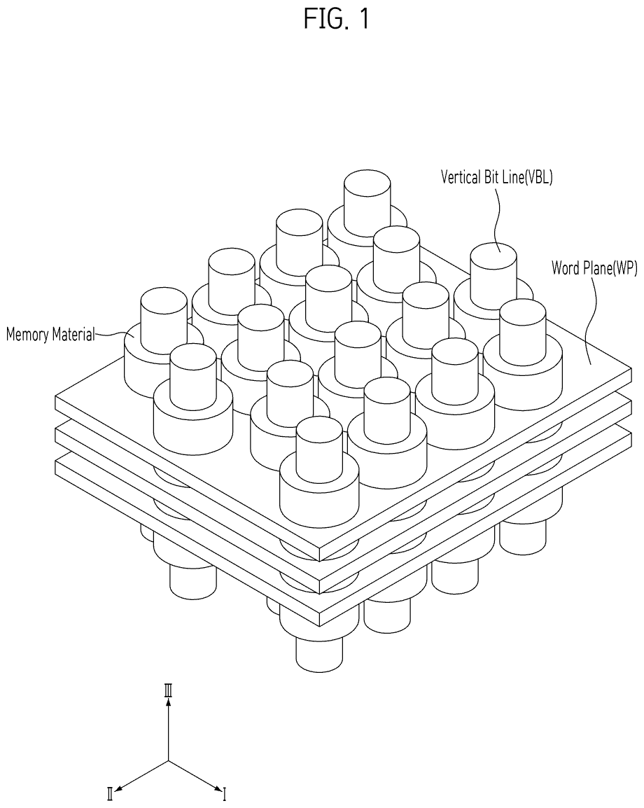

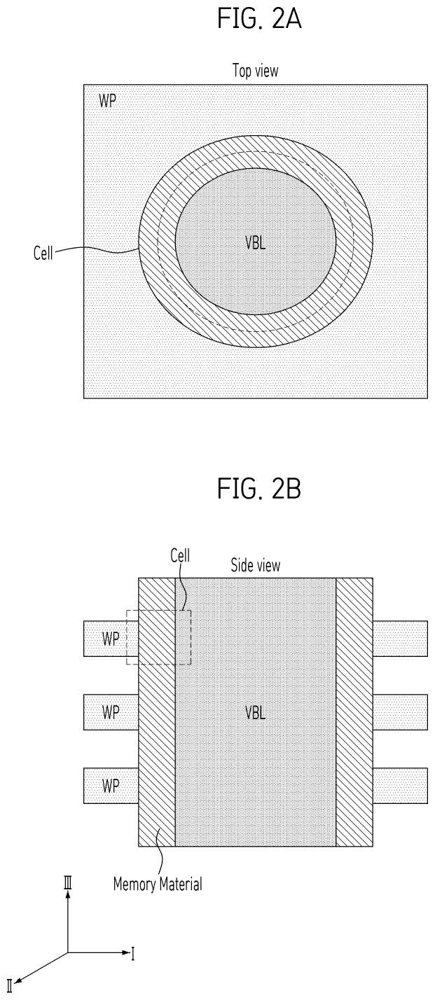

FIG. 1 illustrates a memory cell array in accordance with an embodiment of the present disclosure. FIG. 1 is a perspective view of the memory cell array. FIG. 2A is a top view of a memory cell included in the memory cell array, and FIG. 2B is a side view of the memory cell.

Referring to FIGS. 1, 2A, and 2B, the memory cell array includes a memory cell, a vertical bit line (VBL), and a word plane (WP).

In an embodiment, the word plane WP extends in a first direction I and a second direction II. When the memory cell array includes a plurality of word planes WP, the memory cell array is configured such that the plurality of word planes WP extend in the first direction I and the second direction II, and are stacked in a third direction III. Each word plane WP includes a conductive material. In such a case, FIG. 1 illustrates at least one word plane WP extending in the first direction I and the second direction II on a plane defined by the first and second directions I and II. However, the number of word planes WP is not limited to the embodiment shown in FIG. 1. For example, in another embodiment, the memory cell array includes a plurality of word planes formed on the same plane defined by the first direction I and the second direction II. In addition, the plurality of word planes are stacked in the third direction III and included in the memory cell array.

In an embodiment, the vertical bit line VBL is formed to extend in the third direction III. In addition, the memory cell array is configured to include a plurality of vertical bit lines VBL extending in the third direction III. The plurality of vertical bit lines VBL each penetrates the word plane WP in the third direction III. The vertical bit line VBL includes a conductive material. For example, the vertical bit line VBL is illustrated as a circular pillar shape; however, embodiments are not limited thereto.

In an embodiment, a memory material layer Memory Material is formed to surround each of the plurality of vertical bit lines VBL. In such a case, the memory material layer Memory Material includes a chalcogenide-based material, and a threshold voltage level of the memory material layer Memory Material is changed depending on a direction of current flowing through the memory material layer Memory Material. In such a case, some sections of the memory material layer Memory Material function as memory cells Cell to perform a data storage operation. As shown in FIG. 2B, a memory cell Cell corresponds to a section of the memory material layer Memory Material that is disposed between the word plane WP and the vertical bit line VBL. A threshold voltage level of the memory cell Cell is changed depending on a current direction between the word plane WP and the vertical bit line VBL.

In summary, the memory cell array in accordance with the embodiment of the present disclosure includes the plurality of word planes WP stacked in the third direction III and extending in the first and second directions I and II, the plurality of vertical bit lines VBL each extending in the third direction III and penetrating the plurality of word planes WP, and the memory material layer Memory Material surrounding each of the plurality of vertical bit lines VBL. As a result, the memory cell array in accordance with the embodiment of the present disclosure includes a plurality of memory cells Cell, each formed between a word plane WP and a vertical bit line VBL.

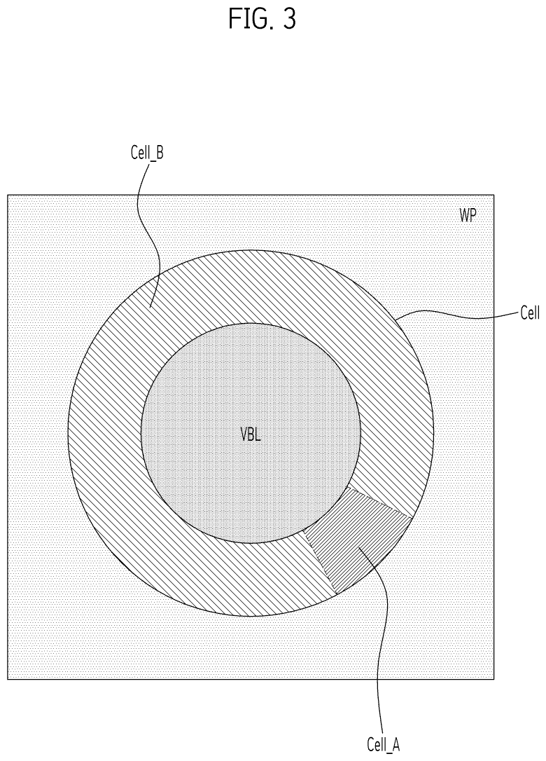

FIG. 3 illustrates a memory cell included in the memory cell array in accordance with an embodiment of the present disclosure. FIG. 3 illustrates a section of the memory material layer Memory Material that is disposed between the vertical bit line VBL and the word plane WP, and the section of the memory material layer Memory Material functions as a memory cell Cell through a firing operation.

Referring to FIG. 3, the section of the memory material layer Memory Material disposed between the word plane WP and the vertical bit line VBL is divided into a first area Cell_A and a second area Cell_B through the firing operation. The first area Cell_A has a lower threshold voltage than the second area Cell_B. The first area Cell_A performs an operation of the memory cell Cell to store data. The second area Cell_B is an area where there is no change in threshold voltage in a voltage or current range in which the first area Cell_A performs a memory operation. Accordingly, the first area Cell_A serves as a data storage region, and is referred to as an active area Cell_A, where a change in threshold voltage occurs in the voltage or current range in which the memory operation is performed.

Accordingly, when a voltage is applied to both the word plane WP and the vertical bit line VBL, and the voltage difference between the word plane WP and the vertical bit line VBL exceeds the threshold voltage level of the active area Cell_A, a current flows between the word plane WP and the vertical bit line VBL through the active area Cell_A. Depending on the current direction at this time, the threshold voltage of the active area Cell_A is changed. For example, when the current flows from the vertical bit line VBL to the word plane WP through the active area Cell_A, the threshold voltage of the active area Cell_A is lower than when the current flows in the opposite direction, from the word plane WP to the vertical bit line VBL through the active area Cell_A.

For example, when a first voltage is applied to the word plane WP and a second voltage having a higher level than the first voltage is applied to the vertical bit line VBL, the current flows from the vertical bit line VBL to the word plane WP through the active area Cell_A. In such a case, the state of the active area Cell_A is changed to a first state.

On the other hand, when the second voltage is applied to the word plane WP and the first voltage having a lower level than the second voltage is applied to the vertical bit line VBL, the current flows from the word plane WP to the vertical bit line VBL through the active area Cell_A. In such a case, the state of the active area Cell_A is changed to a second state. The threshold voltage of the active area Cell_A in the first state is different from that in the second state. The voltage difference between the first voltage and the second voltage is greater than the threshold voltage level of the active area Cell_A.

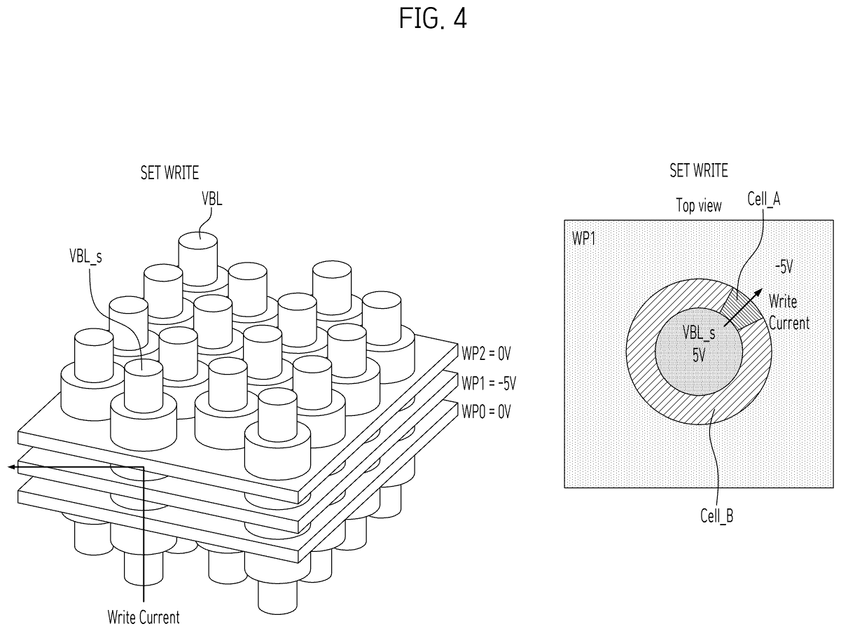

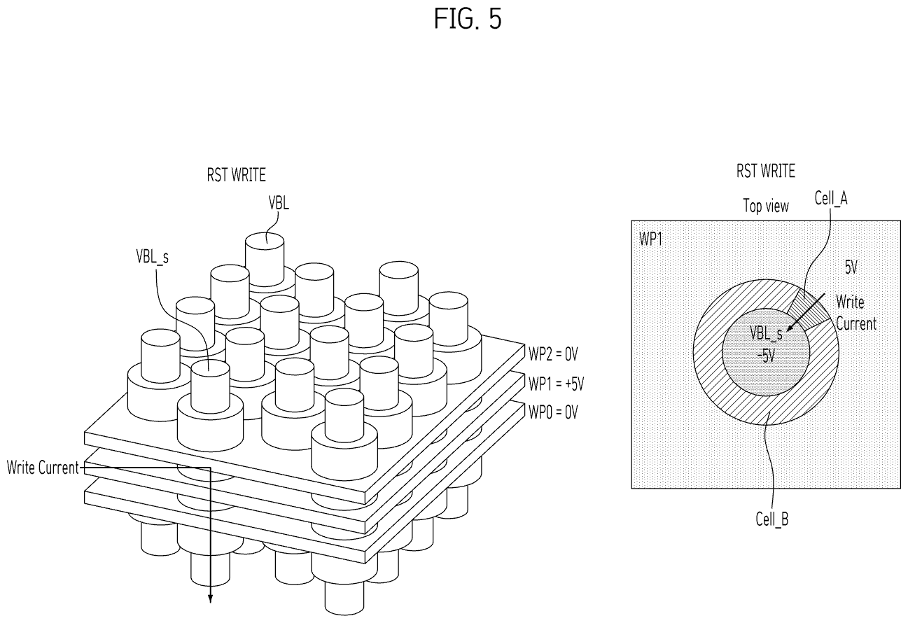

FIGS. 4 and 5 describe a write operation of the memory cell array in accordance with an embodiment of the present disclosure.

By performing the write operation, a state of a selected memory cell among a plurality of memory cells in the memory cell array is changed to a first state or a second state. A memory cell in the first state has a threshold voltage lower than a threshold voltage of a memory cell in the second state. The first state is referred to as a set state SET, and the second state is referred to as a reset state RST. Accordingly, a write operation of changing the state of the selected memory cell to the first state, that is, the set state SET, is referred to as a set write operation SET WRITE. A write operation of changing the state of the selected memory cell to the second state, that is, the reset state RST, is referred to as a reset write operation RST WRITE.

FIG. 4 depicts the set write operation SET WRITE of changing the state of the selected memory cell to the set state SET.

Referring to FIG. 4, the set write operation SET WRITE is performed by selecting at least one word plane WP1 among a plurality of word planes WP0, WP1, and WP2 and selecting at least one vertical bit line VBL_s among a plurality of vertical bit lines VBL. In this case, a first voltage is applied to the selected word plane WP1, and a second voltage is applied to the selected vertical bit line VBL. The second voltage has a higher level than the first voltage. The first voltage may be a negative voltage, and the second voltage may be a positive voltage. For example, the first voltage is −5 V, and the second voltage is 5 V. During the set write operation SET WRITE, the unselected word planes WP0 and WP2 are grounded.

Accordingly, during the set write operation SET WRITE, a write current flows from the selected bit line VBL_s to the selected word plane WP1. In this case, when viewed from the top view of the selected word plane WP1, the write current can be seen flowing from the selected bit line VBL_s to the selected word plane WP1 through the active area Cell_A.

As a result, the threshold voltage of the active area Cell_A during the set write operation SET WRITE is formed to have a lower level than the threshold voltage during the reset write operation RST WRITE.

Therefore, the active area Cell_A, formed between the selected word plane WP1 and the selected bit line VBL_s, functions as a memory cell, with its threshold voltage changing based on the direction of a current flowing through the active area Cell_A.

FIG. 5 depicts the reset operation RST WRITE of changing the state of the selected memory cell to the reset state RST.

Referring to FIG. 5, the reset write operation RST WRITE is performed by selecting at least one word plane WP1 among the plurality of word planes WP0, WP1, and WP2 and selecting at least one vertical bit line VBL_s among the plurality of vertical bit lines VBL. In this case, a first voltage is applied to the selected vertical bit line VBL_s, and a second voltage is applied to the selected word plane WP1. The first voltage has a lower level than the second voltage. The first voltage may be a negative voltage, and the second voltage may be a positive voltage. For example, the first voltage is −5 V, and the second voltage is 5 V. During the reset write operation RST WRITE, the unselected word planes WP0 and WP2 are grounded.

Accordingly, during the reset write operation RST WRITE, a write current flows from the selected word plane WP1 to the selected vertical bit line VBL_s. In this case, when viewed from the top view of the selected word plane WP1, the write current can be seen flowing from the selected word plane WP1 to the selected vertical bit line VBL_s through the active area Cell_A.

As a result, the threshold voltage of the active area Cell_A during the reset write operation RST WRITE is formed to have a higher level than the threshold voltage during the set write operation SET WRITE.

Therefore, the active area Cell_A, formed between the selected word plane WP1 and the selected bit line VBL_s, functions as a memory cell, with its threshold voltage changing based on the direction of a current flowing through the active area Cell_A.

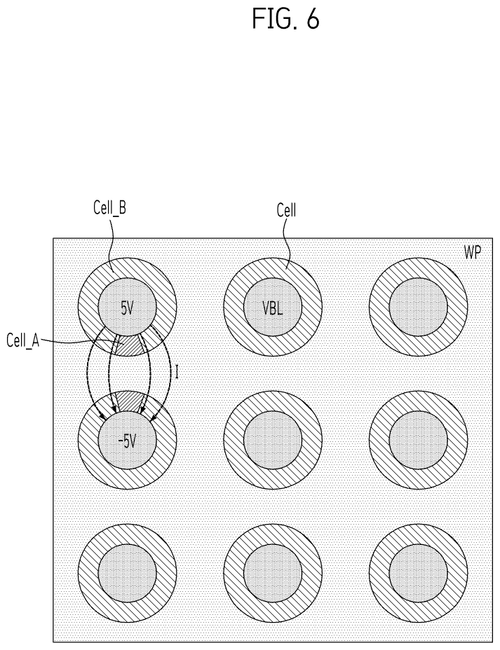

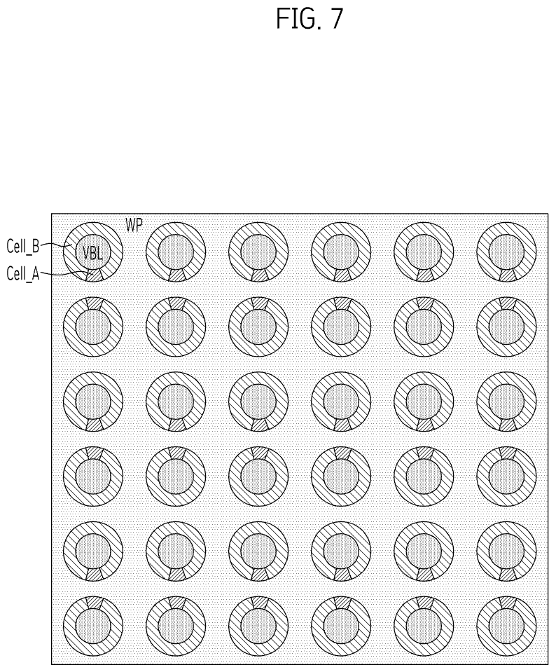

FIGS. 6 and 7 describe a firing operation of the memory cell array in accordance with an embodiment of the present disclosure. The firing operation is an operation for forming a part of a memory material layer Memory Material formed between a word plane WP and a vertical bit line VBL into an active area Cell_A. The active area Cell_A formed by the firing operation is an area having a lower threshold voltage than an area Cell_B that is the remaining part of the memory material layer Memory Material.

In a state where the word plane WP is floated, a first voltage of −5 V is applied to one of two selected vertical bit lines, while a second voltage of 5 V is applied to the other of the two selected vertical bit lines. The two selected vertical bit lines form a pair.

In this case, a current flows from the vertical bit line to which the second voltage of 5 V has been applied to the vertical bit line to which the first voltage of −5 V has been applied. Among areas of memory cells Cell surrounding the pair of selected vertical bit lines, each area through which the current flows is formed as the active area Cell_A.

Accordingly, in the memory cell array in accordance with the embodiment of the present disclosure, a pair of active areas Cell_A is formed, facing each other along the pair of selected vertical bit lines during the firing operation.

When an operation of selecting a pair of vertical bit lines and applying the first voltage of −5 V and the second voltage of 5 V to the pair of selected vertical bit lines is sequentially repeated, pairs of facing active areas Cell_A are formed. As a result, active areas of a plurality of memory cells included in one word plane are arranged in facing pairs, as illustrated in FIG. 7.

As described above, in the memory cell array in accordance with the embodiment of the present disclosure, a pair of active areas facing each other is formed based on a pair of selected vertical bit lines during the firing operation. In addition, by repeating this operation, active areas of memory cells included in a word plane are formed to face each other.

Therefore, the memory cell array includes regularly arranged active areas.

As described above, the firing operation of the memory cell array, as illustrated in FIGS. 6 and 7, is an example of the firing operation for one word plane among the plurality of word planes WP0, WP1, and WP2 stacked in the third direction III.

In another embodiment, in the firing operation of the memory cell, a set number of word planes among the plurality of word planes WP0, WP1, and WP2 are floated, allowing simultaneous firing operations for the floated word planes.

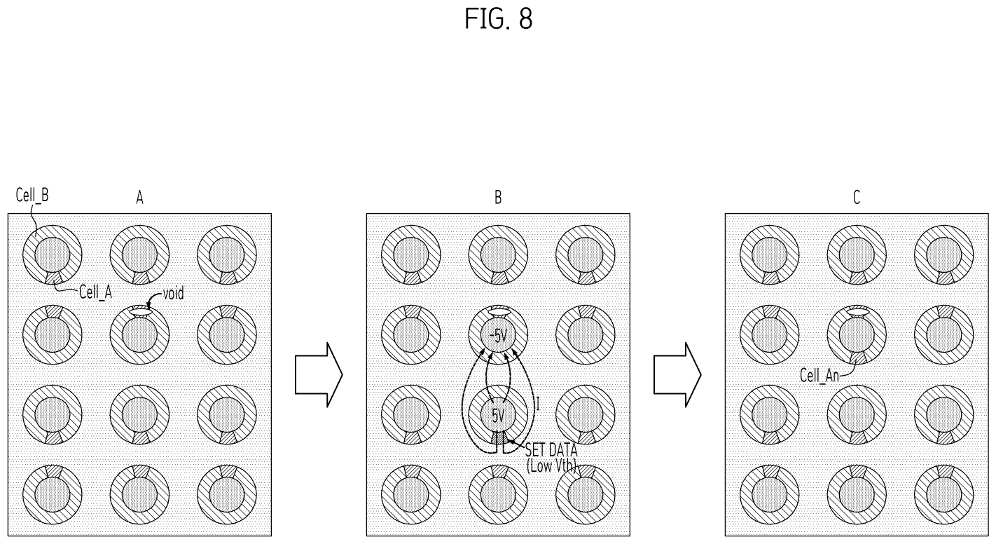

FIG. 8 describes an operation of a memory apparatus in accordance with an embodiment of the present disclosure. FIG. 8 illustrates a repair operation of a failed cell that does not function normally as a memory cell.

Referring to FIG. 8A, a void occurs in one memory cell, that is, in an active area Cell_A. The active area Cell_A including the void does not function normally as a memory cell. The void may occur in the active area Cell_A when a read operation or a write operation is repeatedly performed on the memory cell. The memory cell including the active area Cell_A where the void occurs is considered a failed cell.

Referring to FIG. 8B, during the repair operation, a vertical bit line closest to a vertical bit line corresponding to the active area Cell_A, where the void occurs, is selected. The selected vertical bit line is different from a vertical bit line that was selected, during a firing operation, to be paired with the vertical bit line corresponding to the active area Cell_A. A state of an active area corresponding to the selected vertical bit line is then set to the set state SET. Subsequently, while the word plane WP is floated, the first voltage of −5 V is applied to the vertical bit line corresponding to the active area Cell_A with the void, and the second voltage of 5 V is applied to the selected vertical bit line.

In such a case, a current flows from the active area corresponding to the selected vertical bit line to the vertical bit line corresponding to the active area Cell_A with the void.

Referring to FIG. 8C, as the current flows as illustrated in FIG. 8B, a new active area Cell_An is formed in the memory cell where the void occurs. The new active area Cell_An is formed in the direction or position closest to the position of the selected vertical bit line.

When the new active area Cell_An is formed in the failed cell, no current flows to the active area Cell_A with the void.

As a result, the threshold voltage of the new active area Cell_An is changed based on the direction of a current between the vertical bit line and the word plane, allowing the previously failed cell to function normally as a memory cell.

In an embodiment, the repair operation of the failed cell is performed after an active area is regularly formed during the firing operation.

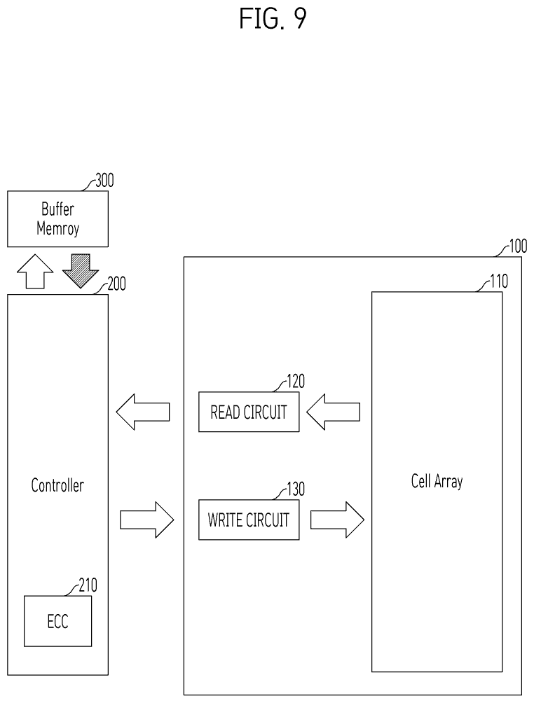

FIG. 9 illustrates a memory system in accordance with an embodiment of the present disclosure.

Referring to FIG. 9, the memory system includes a memory apparatus 100, a controller 200, and a buffer memory 300.

The memory apparatus 100 includes a memory cell array 110, a read circuit 120, and a write circuit 130.

As illustrated in FIGS. 1 and 2, the memory cell array 110 includes a plurality of vertical bit lines, a plurality of word planes, and a plurality of memory material layers. For example, each of the plurality of word planes is formed in a plane defined by the first and second directions I and II, and the plurality of word planes are stacked in the third direction III. Each of the plurality of vertical bit lines is formed to penetrate the plurality of stacked word planes in the third direction III, and each of the plurality of vertical bit lines is surrounded by a corresponding one of the plurality of memory material layers. In such a case, a section of a memory material layer located between a word plane and a vertical bit line serves as a memory cell.

In an embodiment, as illustrated in FIGS. 6 and 7, while the word plane is floated, the memory cell array 110 performs a firing operation by applying a first voltage and a second voltage to two selected vertical bit lines of a pair, respectively. In addition, by repeatedly selecting a pair of vertical bit lines and performing the firing operation thereon, active areas facing each other in each pair are formed in the memory cells included in the memory cell array 110.

In an embodiment, the memory cell array 110 is in a state in which the firing operation, in accordance with the embodiment of the present disclosure, has been completed on all memory cells.

In an embodiment, the read circuit 120 senses and determines data stored in the memory cells of the memory cell array 110 under the control of the controller 200, and transmits the determined data to the controller 200. The read circuit 120 is configured to select at least one word plane constituting the memory cell array 110, to select at least one vertical bit line, and to select at least one memory cell. The read circuit 120 senses and determines data stored in the selected memory cell and transmits the determined data to the controller 200.

In an embodiment, the write circuit 130 stores data in the memory cells of the memory cell array 110 under the control of the controller 200. The write circuit 130 is configured to select at least one word plane constituting the memory cell array 110, to select at least one vertical bit line, and to select at least one memory cell. As illustrated in FIGS. 4 and 5, the write circuit 130 stores data in the selected memory cell by performing a set write operation or a reset write operation.

In an embodiment, the controller 200 controls data to be stored in the memory cell array 110 of the memory apparatus 100 or the data stored in the memory cell array 110 to be output in response to a request of a host. In addition, the controller 200 includes an ECC circuit 210 to check whether data received from the memory apparatus 100 includes an error and to correct the error.

In an embodiment, the buffer memory 300 stores data received from the controller 200 or output the stored data to the controller 200 under the control of the controller 200.

In an embodiment, the memory system in accordance with the embodiment of the present disclosure configured as described above operates as follows.

In an embodiment, the controller 200 controls the memory apparatus 100 to store data in the memory apparatus 100 or output the data stored in the memory apparatus 100. In such a case, the controller 200 corrects an error in data received from the memory apparatus 100 through the ECC circuit 210.

In an embodiment, when an error continues to occur in the same address, the controller 200 determines that a memory cell at the address is a failed cell.

In an embodiment, in a repair operation, the controller 200 selects a vertical bit line closest to a vertical bit line of the failed cell and receives data stored in a memory cell of the selected vertical bit line through the read circuit 120. The controller 200 stores the received data in the buffer memory 300. The selected vertical bit line is selected from among vertical bit lines that were not paired with the vertical bit line of the failed cell during the firing operation. In the repair operation, the read circuit 120 selects a word plane where the failed cell is located, selects the vertical bit line closest to the vertical bit line of the failed cell, and reads out data stored in a memory cell corresponding to the selected vertical bit line, so that the data is transmitted to the controller 200.

Subsequently, the controller 200 performs a set write operation SET WRITE on the memory cell between the selected word plane and the selected vertical bit line.

In the set write operation SET WRITE, while floating the selected word plane where the failed cell is located, the controller 200 applies the first voltage of −5 V to the vertical bit line of the failed cell, and applies the second voltage of 5 V to the selected vertical bit line. As a result, ss illustrated in FIG. 8B, a current flows from the selected vertical bit line to the vertical bit line of the failed cell through the selected word plane. Accordingly, as illustrated in FIG. 8C, a new active area is formed between the vertical bit line of the failed cell and the selected word plane. The new active area is formed in the direction of the selected vertical bit line. The controller 200 applies the first voltage of −5 V to the vertical bit line of the failed cell through the write circuit 130 as illustrated in FIG. 5, and applies the second voltage of 5 V to the selected vertical bit line through the write circuit 130 as illustrated in FIG. 4.

Subsequently, the controller 200 migrates the data stored in the buffer memory 300 to the memory cell between the selected vertical bit line and the word plane including the failed cell through the write circuit 130. As a result, the data of the memory cell between the selected vertical bit line and the word plane is recovered after the repair operation for the failed cell is completed.

In this way, the memory system in accordance with the embodiment of the present disclosure can repair the failed cell to normally operate again to perform a normal operation such as a write operation or a read operation.

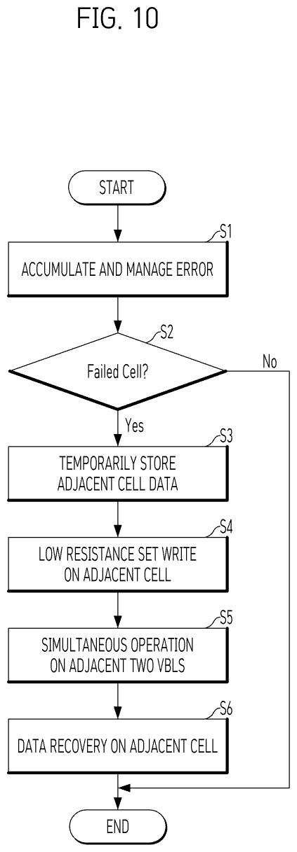

FIG. 10 is a flowchart for describing an operation of the memory system in accordance with an embodiment of the present disclosure.

Referring to FIG. 10, the operating method of the memory system includes an error accumulation management step S1, a failed cell determination step S2, a temporary data storage step S3, a set write execution step S4, a simultaneous operation step S5, and a data recovery step S6.

In an embodiment, the error accumulation management step S1 includes a step in which the controller 200 receives data from the memory apparatus 100 and corrects an error in the received data, and a step in which the controller 200 accumulates information on an address where the error has occurred and stores the accumulated information.

In an embodiment, the failed cell determination step S2 includes a step of determining a failed cell based on the accumulated information. In the failed cell determination step S2, when it is determined that the error has occurred for the same address more than a preset number of times, a corresponding memory cell is determined as a failed cell.

When the memory cell is determined as the failed cell in the failed cell determination step S2 (Yes), the temporary data storage step S3 is performed.

On the other hand, when the memory cell is not determined as the failed cell in the failed cell determination step S2 (No), the operating method of the memory system is ended. After the operating method is ended, the memory system requests the memory apparatus to perform a normal operation such as a read operation or a write operation.

In an embodiment, the temporary data storage step S3 includes a step of storing data of a memory cell adjacent to the failed cell in the buffer memory 300. The adjacent memory cell is a memory cell formed between the same word plane as that of the failed cell and a vertical bit line closest to a vertical bit line of the failed cell. In addition, the vertical bit line of the adjacent memory cell is a vertical bit line that has not been selected as a pair with the vertical bit line of the failed cell during a firing operation.

In an embodiment, the set write execution step S4 includes a step of performing a set write operation SET WRITE on the adjacent memory cell in the temporary data storage step S3. In such a case, a state of the adjacent memory cell is changed to a set state SET. Accordingly, through the set write execution step S24, the state of the adjacent memory cell is changed to have lower resistance than the resistance of a reset state RST.

In an embodiment, the simultaneous operation step S5 includes a step of applying the first voltage of −5 V and the second voltage of 5 V to the vertical bit line of the failed cell and the vertical bit line of the adjacent memory cell, respectively, while floating the word plane including the failed cell. For example, the simultaneous operation step S5 includes a step of applying the first voltage of −5 V to the vertical bit line of the failed cell and simultaneously applying the second voltage of 5 V to the vertical bit line of the adjacent memory cell. In such a case, a new active area is formed in the failed cell in the direction of the vertical bit line of the adjacent memory cell. As a result, the failed cell including the new active area operates as a normal memory cell.

In an embodiment, the data recovery step S6 includes a step of storing the data stored in the buffer memory 300 in the adjacent memory cell on which the set write operation has been performed in the set write execution step S4. That is, the data stored in the buffer memory 300 is migrated to the adjacent memory cell. That is, the data recovery step S6 is a step of recovering the data to the adjacent memory cell used for repairing the failed cell.

After the data recovery step S6, the operating method is ended, and the memory system performs a normal operation such as a read operation or a write operation again.

Through the operating method of the memory system in accordance with the embodiment of the present disclosure, the memory system can repair a failed cell in the memory apparatus.

Although embodiments according to the technical idea of the present disclosure have been described above with reference to the accompanying drawings, this is only for explaining the embodiments according to the concept of the present disclosure, and the present disclosure is not limited to the above embodiments. Various types of substitutions, modifications, and changes for the embodiments may be made by those skilled in the art, to which the present disclosure pertains, without departing from the technical idea of the present disclosure defined in the following claims, and it should be construed that these substitutions, modifications, and changes belong to the scope of the present disclosure.

What is claimed is:

1. An operating method of a memory apparatus, the operation method comprising:
selecting a pair of vertical bit lines from a plurality of vertical bit lines that penetrate a word plane;
floating the word plane; and
applying a first voltage to one vertical bit line in the pair of vertical bit lines and applying a second voltage to the other vertical bit line in the pair of vertical bit lines.

2. The operating method of a memory apparatus of claim 1, wherein the operating method is performed during a manufacturing process of the memory apparatus.

3. The operating method of a memory apparatus of claim 1, wherein the operating method is performed when a failed cell is found in memory cells corresponding to the one vertical bit line during an operation of the memory apparatus.

4. The operating method of a memory apparatus of claim 1, further comprising:
repeating the selecting a pair of vertical bit lines, the applying a first voltage to one vertical bit line, and the applying a second voltage to the other vertical bit line.

5. The operating method of a memory apparatus of claim 1, wherein the first voltage has a lower level than the second voltage.

6. The operating method of a memory apparatus of claim 5, wherein the first voltage is a negative voltage and the second voltage is a positive voltage.

7. The operating method of a memory apparatus of claim 1, wherein the selecting comprises:
selecting a pair of vertical bit lines adjacent to each other.

8. An operating method of a memory system including a memory apparatus, the operating method comprising:
correcting an error in data received from the memory apparatus, accumulating information on an address where the error has occurred, and storing the accumulated information;
determining a failed cell based on the accumulated information;
temporarily storing data of a memory cell adjacent to the failed cell;
changing a state of the adjacent memory cell to a set state;
applying voltages with different levels to a vertical bit line of the failed cell and a vertical bit line of the adjacent memory cell, respectively; and
migrating the data stored temporarily to the adjacent memory cell.

9. The operating method of claim 8, wherein determining a failed cell based on the accumulated information comprises:
determining a memory cell corresponding to the address as the failed cell when it is determined, based on the accumulated information, that the error has occurred for the address more than a preset number of times.

10. The operating method of claim 8, wherein the adjacent memory cell is disposed between a vertical bit line adjacent to the vertical bit line of the failed cell and a word plane including the failed cell.

11. The operating method of claim 9, wherein the temporarily storing comprises:
storing the data of the adjacent memory cell in a buffer memory of the memory system.

12. The operating method of claim 10, wherein the changing comprises:
applying a first voltage to the word plane; and
applying a second voltage having a higher level than the first voltage to the adjacent vertical bit line.

13. The operating method of claim 12, wherein the applying voltages with different levels comprises:
floating the word plane;
applying the first voltage to the vertical bit line of the failed cell; and
applying the second voltage to the vertical bit line of the adjacent memory cell.

14. A memory system, comprising:
a memory apparatus comprising a memory cell array that includes a plurality of memory cells, wherein active areas of each pair of adjacent memory cells among the plurality of memory cells are disposed to face each other;
a controller that controls the memory apparatus; and
a buffer memory that stores data received from the controller and provides the stored data to the controller.

15. The memory system of claim 14, wherein the controller controls the memory apparatus to store data in active areas of the plurality of memory cells and receives the data stored in the active areas of the plurality of memory cells.

16. The memory system of claim 15, wherein the controller corrects an error in data received from the memory apparatus and manages information on an address where the error has occurred.

17. The memory system of claim 16, wherein the controller accumulates the information on the address where the error has occurred, stores the accumulated information, and determines a memory cell corresponding to the address as a failed cell when it is determined, based on the accumulated information, that the error has occurred for the address more than a preset number of times.

18. The memory system of claim 17, wherein the controller stores data of a memory cell adjacent to the failed cell in the buffer memory.

19. The memory system of claim 18, wherein the adjacent memory cell is a memory cell disposed between a vertical bit line adjacent to a vertical bit line of the failed cell and a word plane including the failed cell.

20. The memory system of claim 19, wherein, in an operation of repairing the failed cell, the memory apparatus floats the word plane under control of the controller, applies a first voltage to the vertical bit line of the failed cell, and applies a second voltage to the adjacent vertical bit line.

21. The memory system of claim 20, wherein the first voltage has a lower level than the second voltage.

22. The memory system of claim 21, wherein, when an operation of applying the first voltage to the vertical bit line of the failed cell and applying the second voltage to the adjacent vertical bit line is ended, the controller migrates the data stored in the buffer memory to the adjacent memory cell.
